(19) United States
(12) Patent Application Publication
(10) Pub. No.: US 2012/0155030 A1
(43) Pub. Date: Jun. 21, 2012

(54) MOLDED PART FOR ACCOMMODATING MULTIPLE ELECTRICAL COMPONENTS

(76) Inventors: Jan Breitenbach, Stuttgart (DE); Thorsten Seidel, Remseck (DE)

(21) Appl. No.: 13/376,498

(22) PCT Filed: Apr. 23, 2010
(86) PCT No.: PCT/EP10/55459

§ 371 Date: Mar. 9, 2012

(30) Foreign Application Priority Data
Jun. 10, 2009 (DE) 10 2009 026 886.3

(51) Int. Cl. H05K 7/20; H05K 13/04

(52) U.S. Cl. 361/704; 29/428

(57) ABSTRACT

A molded part is provided for accommodating multiple electrical components and for fastening to an electrical assembly, the molded part including at least one heat sink for cooling an electrical component to be cooled, the molded part being provided to be electrically nonconductive.

### BACKGROUND OF THE INVENTION

1. Field of the Invention

The present invention relates to a molded part for accommodating multiple electrical components.

2. Description of Related Art

Heat sinks are often required for power electronic devices in order to extract the heat generated in the power components. Heat sinks made of metal, e.g., aluminum or copper, which have a simple geometry, are traditionally used for this purpose. Such heat sinks are mostly bent sheet metal parts or extrusion-molded sections, which may be manufactured very cost-effectively. The heat sinks are fastened to an electrical assembly, a circuit board, for example, and the power components are pressed onto the heat sinks with the aid of a screw or a rivet, for example.

If multiple electrical components must be cooled, they must be electrically insulated from each other. Such an insulation is conventionally accomplished with the aid of insulating foils or insulating sleeves, for example. The disadvantages of this approach are that it causes the thermal connection to deteriorate, and that the assembly is complex due to the introduction of insulating foils or insulating sleeves.

The disadvantage of conventional metallic heat sinks is that they often have sharp edges and burrs, which may damage, for example, the insulating foils or insulating sleeves or the insulation of cables, in particular in the event of exposure to vibrations or due to heat generation and which attacks the insulation. Such sharp edges and burrs therefore represent a risk for a short-circuit.

Published German patent application document DE 10 2004 002 743 A1 discloses a heat sink for a power electronic device, which is coated using an electrically well-insulating surface coating, which at the same time makes heat extraction possible. Multiple electrical power components, spaced apart from each other to avoid short-circuits, may be mounted on the coating of the heat sink.

Published European patent document EP 1 887 621 A2 also discloses a heat sink for a power electronic device. It provides a positioning device, using which the components to be cooled may be pre-assembled between a circuit board and the heat sink in any positional relationship to each other to be subsequently fastened to the circuit board with the aid of fastening elements.

An object of the present invention is to provide a cost-effective device and a cost-effective method which allow for a quick and simple assembly of electrical components requiring at least occasional cooling, reliable insulation between the electrical components being ensured.

The object of the present invention is achieved by using a molded part which is provided for accommodating multiple electrical components and for fastening to an electrical assembly, the molded part including at least one heat sink for cooling an electrical component to be cooled, the molded part being provided to be electrically nonconductive.

The molded part according to the present invention allows the electrical components to be rapidly and easily pre-assembled. Due to its nonconductive property, it has the advantage that a risk for a short-circuit between the components is eliminated from the beginning.

The molded part is preferably provided for at least two electrical components to be cooled, it including one heat sink for each electrical component to be cooled. Since the molded part is provided to be nonconductive according to the present invention, this separation of the heat sinks ensures the insulation of the electrical components to be cooled from one another even when multiple electrical components to be cooled are situated on the molded part.

In one preferred specific embodiment, the at least one heat sink has an at least partially flat surface, which is in contact with the electrical component to be cooled, so that the largest possible cooling surface area is provided.

In another preferred specific embodiment, the heat sink extends at least partially along the molded part. On the one hand, the heat sink is thus advantageously adaptable to the molded part, so that a reliable and simple fastening of the heat sink onto or into the molded part is possible. The heat sink may thus be inserted into the molded part, for example. In addition, the heat sink area increases, so that a more extensive and thus more efficient cooling of the component to be cooled is possible.

The at least one heat sink is preferably formed from a metal or a metal alloy, in particular from a sheet metal. Forming the molded part from a plastic is also preferred. Or, the molded part may be formed from a ceramic.

However, there is basically also the possibility to form the molded part from a metal, e.g., aluminum or copper, or a metal alloy, specifically from a sheet metal or as an extrusion-molded section or as a casting, for example. In this case, the molded part is provided with a nonconductive coating, at least in the areas of the conductive parts of the electrical components, so that short-circuits are reliably prevented. However, the entire surface of the molded part is then preferably coated.

Integrating the heat sink into such a nonconductive molded part ensures, in addition to the electrical insulation, that electrical connecting wires and cables are not damaged by metallic burrs.

The heat sink made of metal or a metal alloy may be situated on the molded part after the latter is manufactured. During this process, the heat sink may be placed, for example, inserted, into the molded part or extrusion-coated by the molded part. Furthermore, the heat sink may be connected to the molded part either reversibly or irreversibly.

Furthermore, the molded part preferably includes a fastening means, in particular a snap-on connection, for fastening the molded part to the electrical assembly, in particular a circuit board. The fastening means ensures a reliable and simple installation of the molded part on the assembly. In the specific embodiment of a snap-on connection, installation in a particularly rapid manner is possible.

An installation means, which allows for a fast installation of the molded part into a housing of an electrical device, in particular an electric tool, is also preferably provided on the molded part. In another preferred specific embodiment, the installation means is situated on the heat sink or the heat sink includes the installation means. The installation means is designed as a clip, for example, which may be placed into a housing shell of the electrical device, so that the connection is reversible and may be established very rapidly. Or, the heat sink has such a clip. Since the connection between the electrical assembly and the electric tool housing is established via the installation means of the molded part or the heat sink, no mechanical stress is applied to the assembly as a result of the installation in the electrical device, so that the assembly is not damaged during the installation and/or as a result of other stresses, in particular during the operation of the device. The installation means may be formed from a plastic or a metal, or a metal alloy, in particular from a sheet metal, and preferably from the cooling plate.

The molded part preferably has fastening means for fastening the electrical components and/or the heat sink, which allow the electrical components and/or the heat sink to be fastened and/or attached to the molded part, in particular during operation or during similar loads on the electrical device. In addition, the fastening means ensure a simple and fast assembly of the components, and, in particular, the possibility of pre-assembly. The molded part, together with the electrical components, may thus be manufactured and stored modularly separate from the electrical assembly. It may therefore be prefabricated and may be used flexibly for different electrical devices.

Locating jaws, clips, links, guides, depressions, press-on and/or snap-on elements may be used as fastening means, for example.

In one preferred specific embodiment, the molded part also includes an area for introducing a casting compound, via which, on the one hand, the electrical components are mechanically fastened very well to the molded part. On the other hand, a casting compound provides good ESD (electrostatic discharge) protection and a good protection against external environmental influences, for example, against moisture.

Furthermore, the molded part preferably has a cable guide and/or feed-throughs for passing through connecting wires of the electrical components to the electrical assembly. A cable guide is, for example, a clip, in particular a U-shaped clip, into which a cable may be reversibly placed. Since the molded part is provided to be nonconductive according to the present invention and is preferably coated with a plastic or is formed from a plastic, the risk of the cable or lines being damaged by burrs on the metallic components, and in particular on the heat sink, is minor.

The object is furthermore achieved by an assembly, which includes a molded part according to the present invention, which is fastened to an electrical assembly. Such an assembly forms a functional unit, which may be prefabricated and pre-manufactured modularly, so that it may be very rapidly and easily installed in an electrical device, in particular also in electrical devices of different types.

The object is furthermore achieved by an electric tool having a molded part according to the present invention. An electric tool is, for example, a drill, a saw, a hedge trimmer, or the like.

The object is furthermore achieved by a method for fastening electrical components in an electric tool, which includes the following steps:
fastening electrical components to a molded part according to the present invention and/or a heat sink of the molded part according to the present invention;
fastening the molded part to an electrical assembly; and
placing the molded part on a housing of the electric tool.

Since the electrical components may be fastened to the molded part in a pre-assembly operation, and the molded part thus equipped may also be fastened to an electrical assembly in a pre-assembly operation, the method allows for modular, very fast, and very simple handling of the molded part according to the present invention. The assembly formed from the electrical assembly and the molded part, or the molded part, equipped or not equipped, as well as the electrical assembly, may be manufactured and stored separately from each other, and may be used independently from each other in different electric tools. Depending on the type or design of the electric tool, the molded part alone or the electrical assembly alone may be adapted to and combined with each other.

### BRIEF DESCRIPTION OF THE DRAWINGS

FIG. 1 shows a specific embodiment of a molded part according to the present invention in a perspective front view.

FIG. 2 shows another specific embodiment of the molded part according to the present invention in a perspective rear view.

FIG. 3 shows the molded part of FIG. 2, together with multiple electrical components.

### DETAILED DESCRIPTION OF THE INVENTION

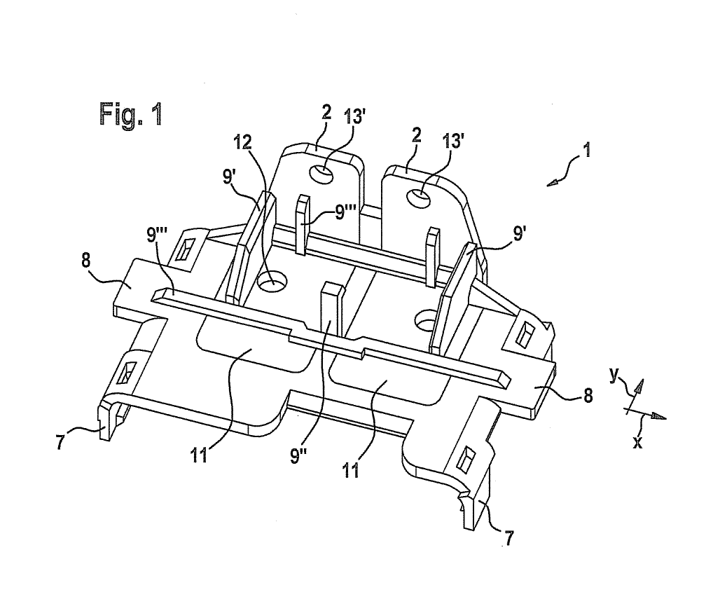

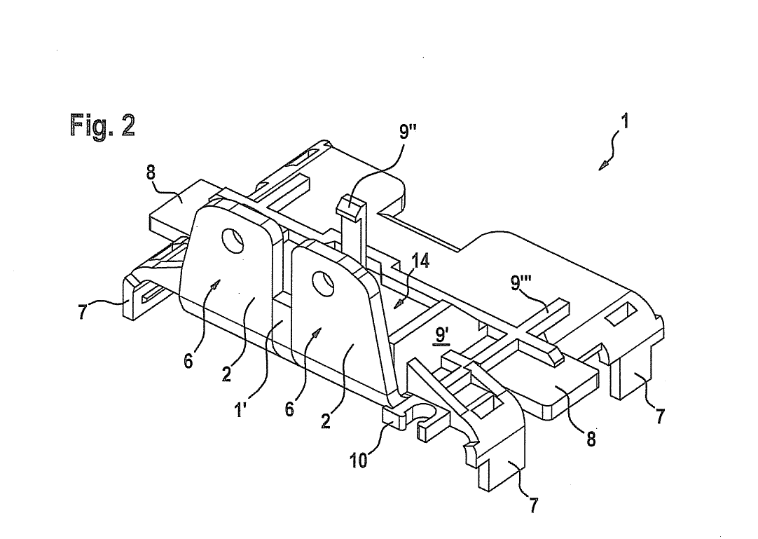

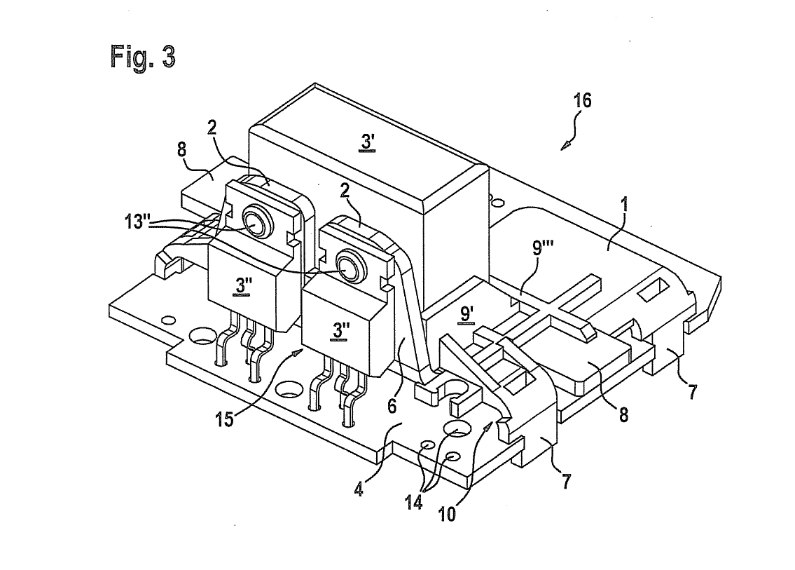

FIG. 1 shows a specific embodiment of a molded part 1 according to the present invention in a perspective front view. Molded part 1 extends essentially in a plane, which is indicated here by two arrows x and y which are perpendicular to each other, and has two heat sinks 2 for cooling electrical components 3″ (see FIG. 3) to be cooled. Heat sinks 2 each have a flat surface 6 (reference numeral shown in FIG. 2), which extends essentially perpendicularly to this plane xy. In addition, they are bent here in an essentially right angle and therefore extend at least partially also into plane xy of molded part 1. For the sake of clarity, this area is identified in FIG. 1 using reference numeral 11. This makes it possible, for example, to insert heat sinks 2 into molded part 1. On the other hand, heat sinks 2 may also be extrusion-coated by molded part 1. In addition, they are spaced apart from each other, a separator 1′ (see FIG. 2) of molded part 1, in the form of a web which extends essentially in the direction of flat surface 6, being situated between heat sinks 2. Heat sinks 2 are thus separated from each other by molded part 1 surrounding them, and web 1′, which is formed between heat sinks 2, ensures the insulation of heat sinks 2 from each other.

Heat sinks 2 each have a positioning means 13′, here a feed-through, for fastening a component 3″ (see FIG. 3) to be cooled.

Fastening means 7 in the form of snap-on connections are provided here for fastening molded part 1 to an electrical assembly 4 (see FIG. 3). Snap-on connections 7 shown here make it possible, in addition to an easy and fast installation of molded part 1 on electrical assembly 4, that the side of the area, extending essentially in plane xy, of molded part 1 facing electrical assembly 4, is spaced from electrical assembly 4, so that after molded part 1 is fastened to electrical assembly 4, a clearance 15 (see FIG. 3) is formed between them in which components 3′, 3″ may be placed and connecting wires and cables may be guided without negatively impacting the functionality of assembly 16 (see FIG. 3) formed from electrical assembly 4 and molded part 1.

Molded part 1 furthermore has fastening means 9′, 9″, 9″′, which are designed here as locating jaws 9′, press-on elements 9″, or guides 9″′ for fastening electrical components 3′ and/or heat sinks 2. Electrical components 3′ and/or heat sinks 2 may be fastened and/or attached to molded part 1 with the aid of fastening means 9′, 9″, and 9″′.

Furthermore, molded part 1 and/or the heat sinks provide(s) feed-throughs 12, through which connecting wires of electrical components 3′ may be passed, so that they are connectable to electrical assembly 4, for example. If feed-throughs 12 are provided in heat sinks 2, they are dimensioned so that contact of the connecting wires with heat sinks 2 is reliably prevented. Alternatively or additionally, it may also be provided that the connecting wires and/or feed-throughs 12 are electrically insulated.

Two clips, which are introduced into the housing shells of the electrical device, are provided on molded part 1 (illustrated here) as installation means 8 for situating molded part 1 on an electrical device (not illustrated), so that instead of electrical assembly 4 (see FIG. 3) being fastened to molded part 1, molded part 1 itself is situated on the housing of the electrical device. This prevents mechanical stresses on electrical assembly 4.

FIG. 2 shows another specific embodiment of molded part 1 according to the present invention in a perspective rear view. In contrast to the specific embodiment of FIG. 1, more guides 9′″ are provided here as fastening means. Furthermore, this specific embodiment provides an area 14 for introducing a casting compound. Furthermore, a cable guide 10 is visible here, which has an essentially U-shaped design and into which a cable may be placed so that it cannot slip.

FIG. 3 shows molded part 1 of FIG. 2, together with multiple electrical components 3′, 3″. Molded part 1 is reversibly fastened to an electrical assembly 4, here a circuit board, with the aid of snap-on connections 7. Circuit board 4 forms an assembly 16 together with molded part 1.

A clearance 15, in which cables may be guided and components of circuit board 4 may be situated, is provided between circuit board 4 and molded part 1; it also provides for ventilation and thus additional cooling.

In the present specific embodiment, two transistors 3″ and one capacitor 3′ to be cooled are provided as electrical components 3′, 3″ for fastening to molded part 1 or to heat sinks 2 of molded part 1. Transistors 3″ are each situated flatly on flat surface 6 of heat sink 2 and fastened to the particular heat sinks 2 with the aid of positioning counter-means 13″, here a screw or rivet, in each case in such a way that they are preferably pressed on its flat surface 6. Positioning means 13′ of heat sink 2 (see FIG. 1) concur with positioning counter-means 13″.

Furthermore, clips 8 used as installation means, as well as locating jaws 9′ and guides 9″′ of molded part 1 used as fastening means are visible. Furthermore, cable guide 10 is shown here.

In addition, feed-throughs 14 are provided on circuit board 4 for the connection of connecting wires and connecting cables.

1-13. (canceled)

14. A molded part, comprising:
a body portion configured to accommodate at least one electrical component to be cooled and configured to fasten to an electrical assembly; and
at least one heat sink for cooling the at least one electrical component;
wherein the molded part is configured to be electrically nonconductive.

15. The molded part as recited in claim 14, wherein the body part is configured to accommodate at least two electrical components to be cooled, and wherein two heat sinks are provided for the two electrical components.

16. The molded part as recited in claim 14, wherein at least a portion of the at least one heat sink has a flat surface which is in contact with the electrical component to be cooled.

17. The molded part as recited in claim 16, wherein the at least one heat sink is formed from a sheet metal.

18. The molded part as recited in claim 16, wherein the molded part is formed from a plastic.

19. The molded part as recited in claim 16, further comprising:
a fastening unit in the form of a snap-on connection for fastening the molded part to the electrical assembly.

20. The molded part as recited in claim 16, wherein an installation arrangement is provided on the heat sink.

21. The molded part as recited in claim 16, further comprising:
a fastening arrangement for fastening at least one of the electrical component and the heat sink.

22. The molded part as recited in claim 11, further comprising:
a cable guide for guiding a connecting cable.

23. The molded part as recited in claim 16, wherein the molded part includes an area for introducing a casting compound.

24. The molded part as recited in claim 16, wherein the molded part is fastened to the electrical assembly.

25. A method for fastening at least one electrical component in an electric tool, the method comprising:
fastening the at least one electrical component to at least one of a molded part and a heat sink of the molded part;
fastening the molded part to an electrical assembly; and
positioning the molded part on a housing of the electric tool.
